(19) United States
(12) Patent Application Publication
(10) Pub. No.: US 2024/0291459 A1
(43) Pub. Date: Aug. 29, 2024

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Tetsuya KIMURA, Nagaokakyo-shi (JP)

(21) Appl. No.: 18/655,594

(22) Filed: May 6, 2024

Related U.S. Application Data
(63) Continuation of application No. PCT/JP2022/042140, filed on Nov. 11, 2022.
(60) Provisional application No. 63/279,249, filed on Nov. 15, 2021.

(51) Int. Cl. H03H 9/02

(52) U.S. Cl. CPC H03H 9/02023; H03H 9/02031; H03H 9/02157

(57) ABSTRACT

An acoustic wave device includes a support including a support substrate, a piezoelectric layer on the support, made of lithium niobate or lithium tantalate, and including a first main surface and a second main surface that oppose each other, and an interdigital transducer electrode on the first main surface of the piezoelectric layer. An acoustic reflection portion is at a position overlapping at least a portion of the IDT electrode in a plan view when viewed along a laminating direction of the support and the piezoelectric layer. The IDT electrode includes a first busbar and a second busbar that oppose each other, first electrode fingers each including one end connected to the first busbar, and second electrode fingers each including one end connected to the second busbar and being interdigitated with the plurality of first electrode fingers.

### CROSS REFERENCE TO RELATED APPLICATIONS

This application claims the benefit of priority to Provisional Application No. 63,279, 249, filed on Nov. 15, 2021, and is a Continuation Application of PCT Application No. PCT/JP2022/042140, filed on Nov. 11, 2022. The entire contents of each application are hereby incorporated herein by reference.

### BACKGROUND OF THE INVENTION

### 1. Field of the Invention

The present invention relates to acoustic wave devices.

### 2. Description of the Related Art

In the related art, an acoustic wave device has been widely used for a filter or the like of a mobile phone. In recent years, as described in U.S. Patent Application Publication No. 2021/0167756, an acoustic wave device using a bulk wave in a thickness shear mode has been proposed. In the acoustic wave device, a piezoelectric layer is provided on a support. A pair of electrodes are provided on the piezoelectric layer. The pair of electrodes face each other on the piezoelectric layer and are connected to different potentials. By applying an alternating-current (AC) voltage between the electrodes, the bulk wave in the thickness shear mode is excited. A plurality of through holes are provided in the piezoelectric layer.

In the acoustic wave device using the bulk wave in the thickness shear mode as described in U.S. Patent Application Publication No. 2021/0167756, an unnecessary wave is generated at a frequency that is lower than a resonant frequency and is located near the resonant frequency. Therefore, there is a concern that electrical characteristics are deteriorated.

### SUMMARY OF THE INVENTION

Example embodiments of the present invention provide acoustic wave devices that are each able to reduce or prevent an unnecessary wave at a frequency that is lower than a resonant frequency and is located near the resonant frequency.

An acoustic wave device according to an example embodiment of the present invention includes a support including a support substrate, a piezoelectric layer provided on the support, is made of lithium niobate or lithium tantalate, and includes a first main surface and a second main surface that oppose each other, and an interdigital transducer (IDT) electrode on the first main surface of the piezoelectric layer. An acoustic reflection portion is located at a position overlapping at least a portion of the IDT electrode in a plan view when viewed along a laminating direction of the support and the piezoelectric layer. The IDT electrode includes a first busbar and a second busbar that oppose each other, first electrode fingers each including one end connected to the first busbar, and second electrode fingers each including one end connected to the second busbar and being interdigitated with the first electrode fingers. d/p is about 0.5 or less, where d is a thickness of the piezoelectric layer and p is a center-to-center distance between a first electrode finger and a second electrode finger that are adjacent to each other. The piezoelectric layer includes at least one through hole, and one of the at least one through hole is provided in a portion of the piezoelectric layer between the first busbar and any one of the second electrode fingers. The piezoelectric layer includes a notch side surface connected to the first main surface and the second main surface and opposing the through hole, and where an inclination angle of the notch side surface is an angle of the notch side surface inclined with respect to a line normal to the first main surface and the second main surface, the inclination angle is an angle other than 0°.

According to example embodiments of the present invention, it is possible to provide acoustic wave devices that are each able to reduce or prevent an unnecessary wave at a frequency that is lower than a resonant frequency and is located near the resonant frequency.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic sectional view taken along line I-I in FIG. 1.

FIG. 3 is a schematic sectional view taken along line II-II in FIG. 1 and illustrating a vicinity of a first gap region according to an example embodiment of the present invention.

FIG. 4 is a schematic sectional view taken along line III-III in FIG. 1 and illustrating a vicinity of a through hole.

FIG. 5 is a schematic sectional view illustrating a vicinity of a first gap region of an acoustic wave device according to a first comparative example along an electrode finger extending direction.

FIG. 6 is a diagram illustrating impedance frequency characteristics in the first example embodiment of the present invention and the first comparative example.

FIG. 7 is a schematic plan view of an acoustic wave device according to a first modified example of the first example embodiment of the present invention.

FIG. 8 is a schematic plan view of an acoustic wave device according to a second modified example of the first example embodiment of the present invention.

FIG. 9 is a schematic plan view of an acoustic wave device according to a third modified example of the first example embodiment of the present invention.

FIG. 10 is a schematic plan view of an acoustic wave device according to a second example embodiment of the present invention.

FIG. 11 is a schematic sectional view taken along line II-II in FIG. 10 and illustrating a vicinity of a first gap region.

FIG. 12 is a schematic sectional view taken along line III-III in FIG. 10 and illustrating a vicinity of a through hole.

FIG. 13 is a schematic sectional view illustrating a vicinity of a first gap region of an acoustic wave device according to a third example embodiment of the present invention along an electrode finger extending direction.

FIG. 14 is a schematic sectional view illustrating a vicinity of a first gap region of an acoustic wave device according to a fourth example embodiment of the present invention along an electrode finger extending direction.

FIG. 15 is a schematic sectional view illustrating a vicinity of a first gap region of an acoustic wave device according to a fifth example embodiment of the present invention along an electrode finger extending direction.

FIG. 16 is a schematic sectional view illustrating a vicinity of a second gap region of the acoustic wave device according to the fifth example embodiment of the present invention along an electrode finger extending direction.

FIG. 17 is a schematic plan view of an acoustic wave device according to a sixth example embodiment of the present invention.

FIG. 18 is a schematic sectional view taken along line II-II in FIG. 17 and illustrating a vicinity of a first gap region.

FIG. 19 is a diagram illustrating impedance frequency characteristics in the sixth example embodiment of the present invention and a second comparative example.

FIG. 20 is a schematic plan view of an acoustic wave device according to a first modified example of the sixth example embodiment of the present invention.

FIG. 21 is a schematic plan view of an acoustic wave device according to a second modified example of the sixth example embodiment of the present invention.

FIG. 22 is a schematic plan view of an acoustic wave device according to a third modified example of the sixth example embodiment of the present invention.

FIG. 23 is a schematic plan view of an acoustic wave device according to a seventh example embodiment of the present invention.

FIG. 24 is a schematic sectional view taken along line II-II in FIG. 23 and illustrating a vicinity of a first gap region along an electrode finger extending direction.

FIG. 25A is a schematic perspective view illustrating an appearance of an acoustic wave device using a bulk wave in a thickness shear mode, and FIG. 25B is a plan view illustrating an electrode structure on a piezoelectric layer.

FIG. 26 is a sectional view of a portion taken along line A-A in FIG. 25A.

FIG. 27A is a schematic elevational sectional view illustrating a Lamb wave that propagates through a piezoelectric film of the acoustic wave device, and FIG. 27B is a schematic elevational sectional view illustrating a bulk wave in a thickness shear mode that propagates through the piezoelectric film of the acoustic wave device.

FIG. 28 is a diagram illustrating an amplitude direction of the bulk wave in the thickness shear mode.

FIG. 29 is a diagram illustrating resonance characteristics of the acoustic wave device using the bulk wave in the thickness shear mode.

FIG. 30 is a diagram illustrating a relationship between d/p and a fractional bandwidth as a resonator in a case where p is a center-to-center distance between electrodes adjacent to each other and d is a thickness of a piezoelectric layer.

FIG. 31 is a plan view of the acoustic wave device using the bulk wave in the thickness shear mode.

FIG. 32 is a diagram illustrating resonance characteristics of an acoustic wave device of a reference example in which a spurious wave appears.

FIG. 33 is a diagram illustrating a relationship between a fractional bandwidth and a phase rotation amount of an impedance of the spurious wave standardized at 180 degrees as a magnitude of the spurious wave.

FIG. 34 is a diagram illustrating a relationship between d/2p and a metallization ratio MR.

FIG. 35 is a diagram illustrating a map of the fractional bandwidth with respect to Euler angles (0°, θ, ψ) of LiNbO₃ in a case where d/p is infinitely close to 0.

FIG. 36 is an elevational sectional view of an acoustic wave device having an acoustic multilayer film according to an example embodiment of the present invention.

### DETAILED DESCRIPTION OF THE EXAMPLE EMBODIMENTS

Hereinafter, the present invention will be clarified by describing example embodiments of the present invention with reference to the accompanying drawings.

Each of example embodiments described in the present specification is merely an example, and partial replacement or combination of the configurations can be made between different example embodiments.

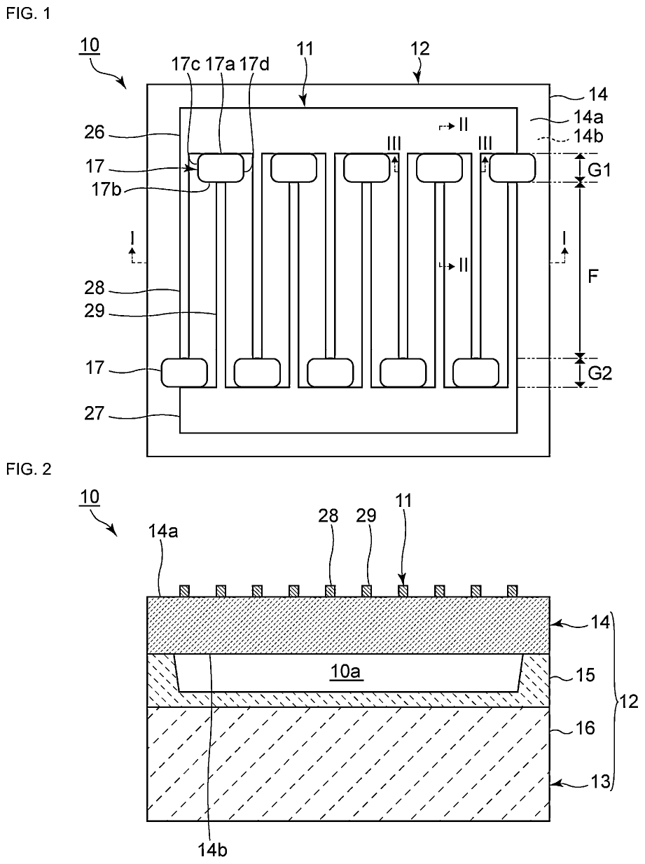

FIG. 1 is a schematic plan view of an acoustic wave device according to a first example embodiment of the present invention. FIG. 2 is a schematic sectional view taken along line I-I in FIG. 1.

As illustrated in FIG. 1, the acoustic wave device 10 includes a piezoelectric substrate 12 and an interdigital transducer (IDT) electrode 11. As illustrated in FIG. 2, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. The support 13 may include only the support substrate 16.

The piezoelectric layer 14 includes a first main surface 14a and a second main surface 14b. The first main surface 14a and the second main surface 14b oppose each other. Of the first main surface 14a and the second main surface 14b, the second main surface 14b is located on the support 13 side.

As the material of the support substrate 16, for example, a semiconductor such as silicon, a ceramic such as aluminum oxide, or the like can be used. As the material of the insulating layer 15, an appropriate dielectric such as silicon oxide or tantalum oxide can be used. The piezoelectric layer 14 is preferably, for example, a lithium niobate layer such as a LiNbO₃ layer or a lithium tantalate layer such as a LiTaO₃ layer.

As illustrated in FIG. 2, a recess portion is provided in the insulating layer 15. The piezoelectric layer 14 is provided on the insulating layer 15 to close the recess portion. As a result, a hollow portion is provided. The hollow portion is a cavity portion 10a. In the present example embodiment, the support 13 and the piezoelectric layer 14 are positioned such that a portion of the support 13 and a portion of the piezoelectric layer 14 oppose each other with the cavity portion 10a interposed therebetween. The recess portion in the support 13 may be provided over the insulating layer 15 and the support substrate 16. Alternatively, the recess portion provided only in the support substrate 16 may be closed by the insulating layer 15. The recess portion may be provided in the piezoelectric layer 14. The cavity portion 10a may alternatively be a through hole provided in the support 13.

The IDT electrode 11 is provided on the first main surface 14a of the piezoelectric layer 14. The acoustic wave device 10 according to the present example embodiment is an acoustic wave resonator configured to use a bulk wave in a thickness shear mode.

In a plan view, at least a portion of the IDT electrode 11 overlaps the cavity portion 10a of the piezoelectric substrate 12. In the present specification, “in a plan view” means viewing in a laminating direction of the support 13 and the piezoelectric layer 14, that is, in a direction from an upper side in FIG. 2. In FIG. 2, for example, the piezoelectric layer 14 side is an upper side of the support substrate 16 and the piezoelectric layer 14.

As illustrated in FIG. 1, the IDT electrode 11 includes a pair of busbars plurality of electrode fingers. Specifically, the pair of busbars include a first busbar 26 and a second busbar 27. The first busbar 26 and the second busbar 27 oppose each other. The plurality of electrode fingers are, specifically, a plurality of first electrode fingers 28 and a plurality of second electrode fingers 29. One end of each of the plurality of first electrode fingers 28 is connected to the first busbar 26. One end of each of the plurality of second electrode fingers 29 is connected to the second busbar 27. The plurality of first electrode fingers 28 and the plurality of second electrode fingers 29 are interdigitated between each other. The IDT electrode 11 may be formed of, for example, a single metal film or a laminated metal film.

Hereinafter, the first electrode finger 28 and the second electrode finger 29 may be simply referred to as an electrode finger. The first busbar 26 and the second busbar 27 may be simply referred to as a busbar. In a case where a direction in which the plurality of electrode fingers extend is an electrode finger extending direction and a direction in which the electrode fingers adjacent to each other oppose each other is an electrode finger facing direction, in the present example embodiment, the electrode finger extending direction and the electrode finger facing direction are orthogonal or substantially orthogonal to each other.

The IDT electrode 11 includes an intersecting region F. The intersecting region F is a region in which the adjacent electrode fingers overlap each other when viewed from the electrode finger facing direction. In the acoustic wave device using the bulk wave in the thickness shear mode, the intersecting region F includes a plurality of excitation regions. Specifically, a region in which the adjacent electrode fingers overlap each other when viewed from the electrode finger facing direction and which is between the centers of the adjacent electrode fingers is the excitation region.

In the acoustic wave device 10, d/p is, for example, about 0.5 or less, where d is a thickness of the piezoelectric layer 14 and p is a center-to-center distance between the adjacent electrode fingers. As a result, the bulk wave in the thickness shear mode is suitably excited.

The cavity portion 10a illustrated in FIG. 2 is an acoustic reflection portion. The acoustic reflection portion can effectively confine the energy of an acoustic wave on the piezoelectric layer 14 side. As the acoustic reflection portion, an acoustic reflection film such as, for example, an acoustic multilayer film described later may be provided.

Returning to FIG. 1, the IDT electrode 11 includes a pair of gap regions. The pair of gap regions are located between the intersecting region F and the pair of busbars. The pair of gap regions are, specifically, a first gap region G1 and a second gap region G2. The first gap region G1 is located between the first busbar 26 and the intersecting region F. The second gap region G2 is located between the second busbar 27 and the intersecting region F.

A plurality of through holes 17 are provided in portions of the piezoelectric layer 14 located in the first gap region G1. More specifically, the through holes 17 are provided in respective portions of the piezoelectric layer 14 between the first busbar 26 and the plurality of second electrode fingers 29. Similarly, a plurality of through holes 17 are provided in portions located in the second gap region G2. More specifically, the through holes 17 are provided in respective portions of the piezoelectric layer 14 between the second busbar 27 and the plurality of first electrode fingers 28. At least one through hole 17 need only be provided in the piezoelectric layer 14. One of the through holes 17 need only be provided in a portion of the piezoelectric layer 14 between the first busbar 26 and any one of the plurality of second electrode fingers 29.

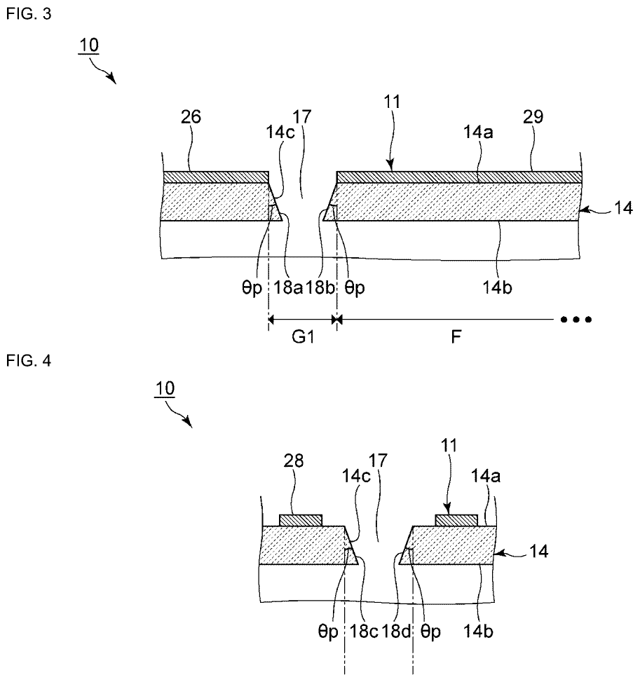

FIG. 3 is a schematic sectional view taken along line II-II in FIG. 1 and illustrating the vicinity of the first gap region. FIG. 4 is a schematic sectional view taken along line III-III in FIG. 1 and illustrating the vicinity of the through hole.

As illustrated in FIGS. 3 and 4, the piezoelectric layer 14 includes a notch side surface 14c. Specifically, the notch side surface 14c is connected to the first main surface 14a and the second main surface 14b and opposes the through hole 17. Hereinafter, an inclination angle θp of the notch side surface 14c is an angle of the notch side surface 14c inclined with respect to a line normal to the first main surface 14a and the second main surface 14b.

As illustrated in FIG. 3, the features of the present example embodiment are that the through hole 17 is provided in the piezoelectric layer 14 between the first busbar 26 and the second electrode finger 29, and the inclination angle θp of the notch side surface 14c opposing the through hole 17 is other than 0°. That is, the notch side surface 14c is inclined with respect to the line normal to the first main surface 14a and the second main surface 14b. As a result, it is possible to effectively disperse the unnecessary waves propagated to the portion in which the through hole 17 is provided. More specifically, it is possible to particularly effectively disperse the unnecessary waves generated in a band that is lower than the resonant frequency and is located near the resonant frequency. Therefore, the unnecessary wave can be suppressed at a frequency that is lower than the resonant frequency and is located near the resonant frequency.

It is preferable that the through hole 17 is also provided in the piezoelectric layer 14 between the second busbar 27 and the first electrode finger 28, and the inclination angle θp of the notch side surface 14c opposing the through hole 17 is other than 0°. As a result, the unnecessary wave can be more reliably suppressed at a frequency that is lower than the resonant frequency and is located near the resonant frequency. The details of the effects of the present example embodiment are illustrated by comparing the present example embodiment with a first comparative example.

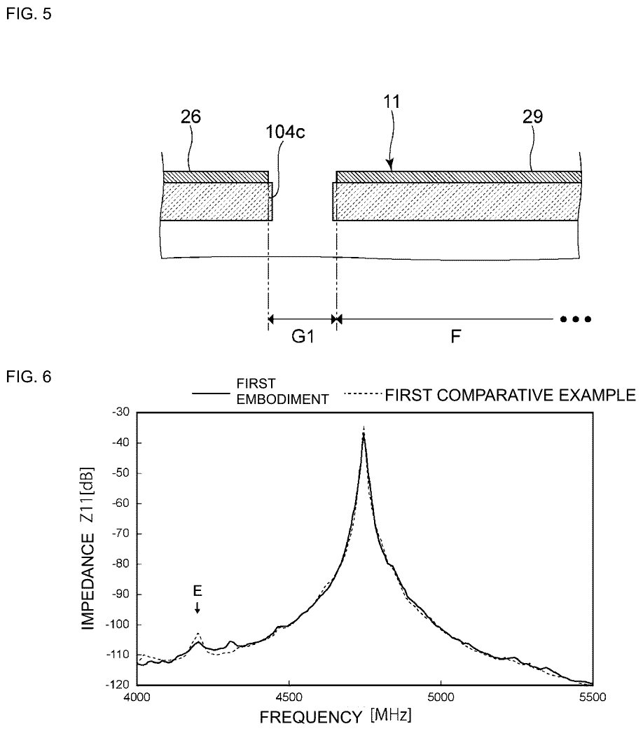

As illustrated in FIG. 5, the first comparative example is different from the first example embodiment in that the inclination angle θp of a notch side surface 104c is 0°. Impedance frequency characteristics of the acoustic wave device according to the first example embodiment and the first comparative example are compared by performing simulation.

FIG. 6 is a diagram illustrating the impedance frequency characteristics according to the first example embodiment and the first comparative example.

As indicated by an arrow E in FIG. 6, in the first comparative example, the ripples caused by the unnecessary waves are generated at a frequency that is lower than the resonant frequency and is located near the resonant frequency. On the other hand, it can be seen that the unnecessary wave generated at the frequency suppressed in the first example embodiment. Hereinafter, in a case where the unnecessary wave is simply described, unless otherwise specified, the unnecessary wave refers to an unnecessary wave generated at a frequency that is lower than the resonant frequency and is located near the resonant frequency.

Hereinafter, the configuration in the first example embodiment will be described in more detail.

Returning to FIG. 1, in the first example embodiment, the through hole 17, which is provided in a portion of the piezoelectric layer 14 located in the first gap region G1, is in contact with the first busbar 26 in a plan view. In the plan view, the through hole 17 is also in contact with the distal end of the second electrode finger 29. On the other hand, the through hole 17 is not in contact with the first electrode finger 28 in the plan view. That is, the through hole 17 is in contact with the busbar and the distal end of the electrode finger that interpose the through hole 17 in the electrode finger extending direction in the plan view and is not in contact with the electrode fingers interposing the through hole in the electrode finger opposing direction. The same applies to the through hole 17 provided in a portion of the piezoelectric layer 14 located in the second gap region G2.

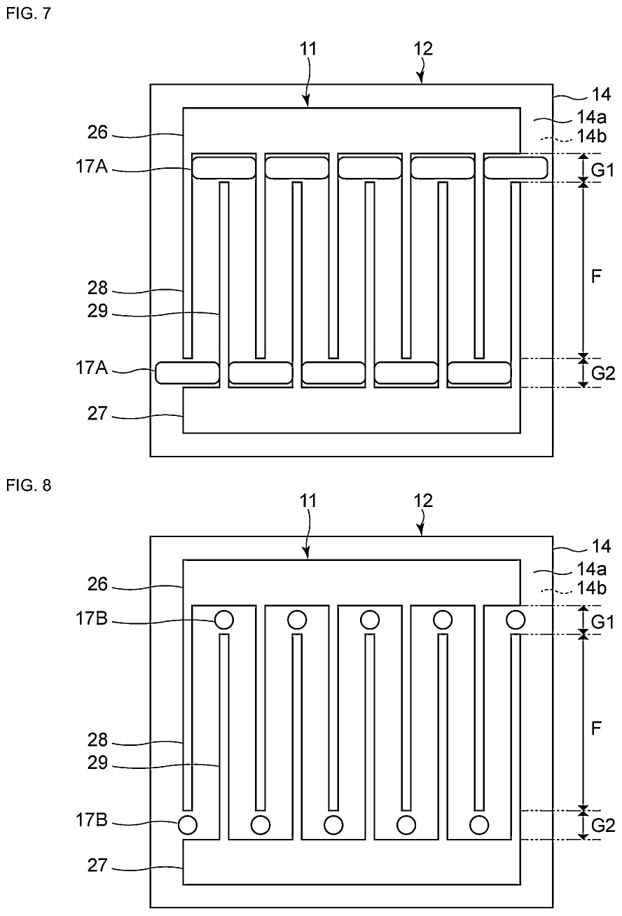

The disposition of the through holes 17 is not limited to the above-described disposition. For example, in a first modified example of the first example embodiment illustrated in FIG. 7, a through hole 17A provided in the portion of the piezoelectric layer 14 located in the first gap region G1 is not in contact with the first busbar 26 in the plan view. The through hole 17A is also not in contact with the distal end of the second electrode finger 29 in the plan view. On the other hand, the through hole 17A is in contact with the first electrode finger 28 in the plan view. That is, the through hole 17A is not in contact with the busbar and the distal end of the electrode finger that interpose the through hole 17A in the electrode finger extending direction in the plan view and is in contact with the electrode fingers interposing the through hole in the electrode finger opposing direction. The same applies to the through hole 17A provided in the portion of the piezoelectric layer 14 located in the second gap region G2.

Also in the present modified example, the inclination angle θp of the notch side surface is preferably an angle other than 0°, as in the first example embodiment. As a result, the unnecessary wave can be reduced or prevented at a frequency that is lower than the resonant frequency and is located near the resonant frequency.

In the first example embodiment and the first modified example, an example of the disposition of the through holes in the piezoelectric layer 14 has been described. The disposition of the through holes is not limited to these examples. For example, the through hole may be in contact with at least any one of the busbar and the distal end of the electrode finger that interpose the through hole in the electrode finger extending direction in the plan view, and the electrode fingers interposing the through hole in the electrode finger opposing direction. Alternatively, the through hole need not be in contact with any of the busbar or the distal end of the electrode finger that interposes the through hole in the electrode finger extending direction in the plan view, or the electrode fingers interposing the through hole in the electrode finger opposing direction.

Returning to FIG. 1, in the first example embodiment, the shape of the through hole 17 provided in the piezoelectric layer 14 is rectangular or substantially rectangular in the plan view. More specifically, the shape of the through hole 17 in the plan view is a shape in which a portion corresponding to a vertex of the rectangular or substantially rectangular shape is curved. As a result, the crack is less likely to occur in the portion of the piezoelectric layer 14 in which the through hole 17 is provided.

The shape of the through hole 17 in the plan view is a shape with a plurality of sides. Specifically, the shape of the through hole 17 in the plan view is a shape including a first side 17a, a second side 17b, a third side 17c, and a fourth side 17d. The first side 17a and the second side 17b oppose each other in the electrode finger extending direction. The third side 17c and the fourth side 17d oppose each other in the electrode finger opposing direction. More specifically, the first side 17a is a side that is located on the busbar side among the busbar and the electrode finger that interpose the through hole 17 in the electrode finger extending direction in the plan view. The second side 17b is a side located on the electrode finger side among the busbars and the electrode fingers.

In example embodiments of the present invention, the shape of the through hole in the plan view is not limited to the above-described shape.

Hereinafter, a second modified example and a third modified example of the first example embodiment will be described in which only the disposition and the shape in the plan view of the through hole provided in the piezoelectric layer are different from those in the first example embodiment. Also in the second modified example and the third modified example, the unnecessary wave can be reduced or prevented at a frequency that is lower than the resonant frequency and is located near the resonant frequency, as in the first example embodiment.

In the second modified example illustrated in FIG. 8, a shape of a through hole 17B in the plan view is a circular or substantially circular shape. The through hole 17B is not in contact with any of the busbar or the distal end of the electrode finger that interposes the through hole 17B in the electrode finger extending direction in the plan view, or the electrode fingers interposing the through hole 17B in the electrode finger opposing direction.

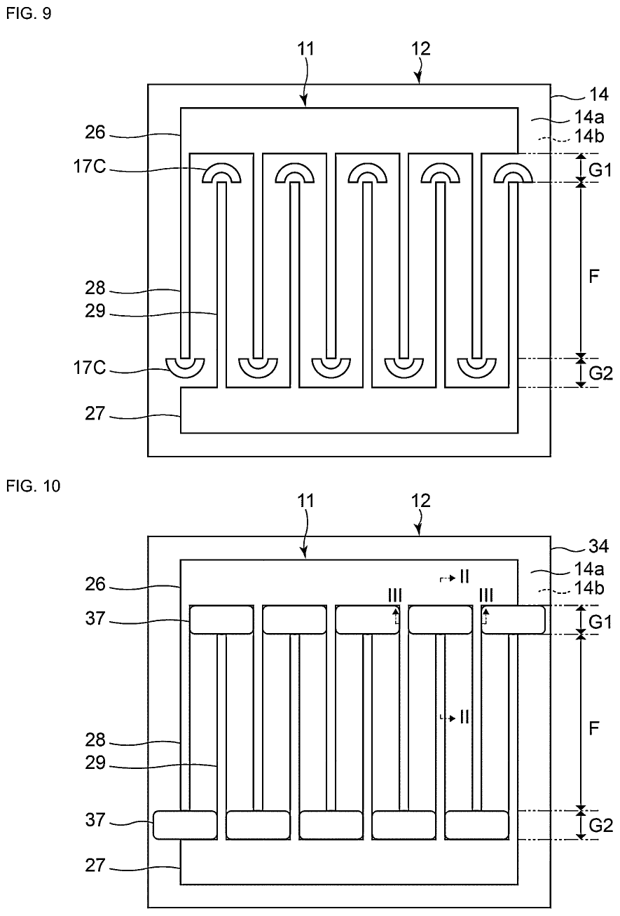

In the third modified example illustrated in FIG. 9, a shape of a through hole 17C in the plan view is preferably in or substantially in a crescent or arch shape. More specifically, the shape of the through hole 17C in the plan view is a shape including two semicircular shapes in which two concentric circles are divided by the same straight line passing through the centers of the two concentric circles, and the two semicircular shapes are connected to each other.

In the plan view, the through hole 17C is not in contact with any of the busbar or the distal end of the electrode finger that interpose the through hole 17C in the electrode finger extending direction, or the electrode fingers interposing the through hole 17C in the electrode finger opposing direction.

The examples of the shape of the through hole in the plan view have been described in the first example embodiment, the second modified example, and the third modified example, but the shape is not limited to these examples.

For example, the shape of the through hole in the plan view may be a triangle, a polygon, or an ellipse shape. The shape of the through hole in the plan view may be a shape in which a portion corresponding to a vertex of a triangle, a quadrangle shape other than rectangle, and a polygon other than the quadrangle shape is curved.

The notch side surface 14c of the piezoelectric layer 14 in the first example embodiment illustrated in FIGS. 3 and 4 preferably includes a plurality of surface portions including the above-described respective sides. Specifically, as illustrated in FIG. 3, the notch side surface 14c includes a first surface portion 18a and a second surface portion 18b. The first surface portion 18a includes the first side 17a illustrated in FIG. 1. The second surface portion 18b includes the second side 17b. As illustrated in FIG. 4, the notch side surface 14c includes a third surface portion 18c and a fourth surface portion 18d. The third surface portion includes the third side 17c illustrated in FIG. 1. The fourth surface portion includes the fourth side 17d.

The notch side surface 14c is inclined such that the distance between the surface portions opposing each other is shortened. In the present example embodiment, the inclination angles θp in the respective surface portions are the same as each other. The present invention is not limited thereto.

It is preferable that, as in the first example embodiment illustrated in FIG. 1, through holes 17 are provided in respective portions of the piezoelectric layer 14 between the first busbar 26 and the plurality of second electrode fingers 29. Similarly, it is preferable that through holes 17 are provided in respective portions of the piezoelectric layer 14 between the second busbar 27 and the plurality of first electrode fingers 28. As a result, the unnecessary wave can be further reduced or prevented more reliably.

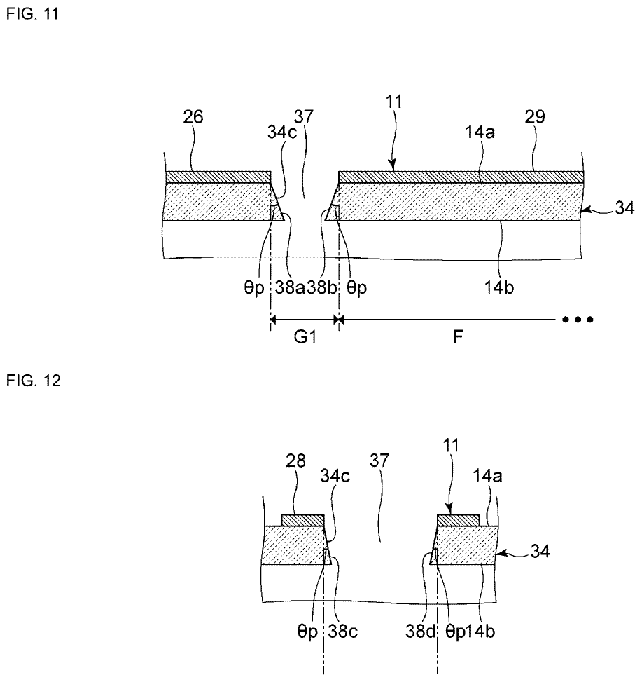

FIG. 10 is a schematic plan view of an acoustic wave device according to a second example embodiment of the present invention. FIG. 11 is a schematic sectional view taken along line II-II in FIG. 10 and illustrating the vicinity of the first gap region. FIG. 12 is a schematic sectional view taken along line III-III in FIG. 10 and illustrating the vicinity of the through hole.

As illustrated in FIG. 10, the present example embodiment is different from the first example embodiment in the disposition of a through holes 37 provided in a piezoelectric layer 34. The present example embodiment is also different from the first example embodiment in a configuration of a notch side surface 34c in the piezoelectric layer 34, as illustrated in FIGS. 11 and 12. Except for the above points, the acoustic wave device according to the present example embodiment has the same configuration as the acoustic wave device 1 according to the first example embodiment.

Returning to FIG. 10, each through hole 37 provided in the piezoelectric layer 34 is in contact with the busbar and the distal end of the electrode finger that interpose the through hole 37 in the electrode finger extending direction in the plan view. Each of the through holes 37 is in contact with both the electrode fingers interposing the through hole 37 in the electrode finger opposing direction in the plan view.

As illustrated in FIG. 11, the notch side surface 34c of the piezoelectric layer 34 includes a first surface portion 38a and a second surface portion 38b. As illustrated in FIG. 12, the notch side surface 34c includes a third surface portion 38c and a fourth surface portion 38d. Hereinafter, among the inclination angles θp of the notch side surface 34c, an inclination angle in the first surface portion 38a is θp1, and an inclination angle in the second surface portion 38b is θp2. Among the inclination angles θp, an inclination angle in the third surface portion 38c is θp3, and an inclination angle in the fourth surface portion 38d is θp4. θp1, θp2, θp3, and θp4 may be collectively referred to as θp.

In the present example embodiment, the inclination angle θp1 of the first surface portion 38a and the inclination angle θp2 of the second surface portion 38b are preferably the same or substantially the same as each other. On the other hand, in the present example embodiment, the inclination angle θp3 of the third surface portion 38c and the inclination angle θp4 of the fourth surface portion 38d may be different from the inclination angle θp1 of the first surface portion 38a. It is preferable that, as in the present example embodiment, the inclination angle θp of at least one surface portion among the plurality of surface portions is different from the inclination angle θp of the other surface portion. As a result, it is possible to effectively disperse the unnecessary waves on the notch side surface 34c.

The configuration in which the inclination angle θp of at least one surface portion among the plurality of surface portions is different from the inclination angle θp of the other surface portion can be used in a configuration of the present invention other than the present example embodiment.

In the first example embodiment and the second example embodiment, the respective surface portions of the notch side surface are uniformly inclined. The notch side surface need not be uniformly inclined. This example is described by a third example embodiment of the present invention.

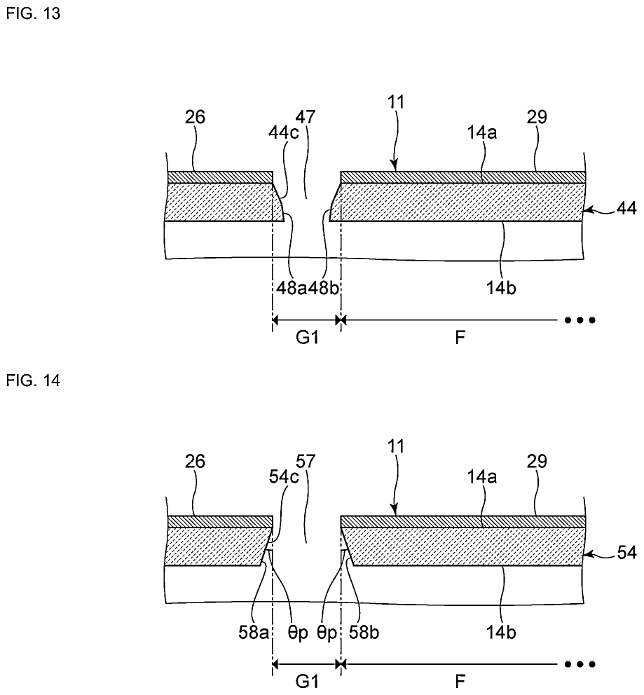

FIG. 13 is a schematic sectional view illustrating a vicinity of a first gap region of an acoustic wave device according to the third example embodiment along the electrode finger extending direction.

The present example embodiment is different from the first example embodiment in that a notch side surface 44c of a piezoelectric layer 44 is not uniformly inclined. Except for the above points, the acoustic wave device according to the present example embodiment preferably has the same or substantially the same configuration as the acoustic wave device 1 according to the first example embodiment.

An inclination angle of a first surface portion 48a of the notch side surface 44c in the piezoelectric layer 44 is changed once from the first main surface 14a side to the second main surface 14b side. The inclination angle may be changed two or more times from the first main surface 14a side to the second main surface 14b side. Similarly, an inclination angle of a second surface portion 48b is also changed from the first main surface 14a side to the second main surface 14b side. Although not illustrated, inclination angles of a third surface portion and a fourth surface portion are also changed in the same manner.

FIG. 13 illustrates each surface portion opposing a through hole 47 provided in a portion of the piezoelectric layer 44 located in the first gap region G1. The inclination angles are preferably changed in the same or substantially the same manner in each surface portion opposing the through hole 47 provided in the portion of the piezoelectric layer 44 located in the second gap region.

As described above, it is preferable that the inclination angle is changed at least once from the first main surface 14a side to the second main surface 14b side. As a result, it is possible to effectively disperse the unnecessary waves on the notch side surface 44c.

As illustrated in FIG. 13, in the present example embodiment, the notch side surface 44c preferably has a shape in which straight lines are connected to each other in a section along the electrode finger extending direction. In the section, the notch side surface 34c may include a curved shape. The same applies to a section along the electrode finger opposing direction.

The configuration in which the inclination angle is changed at least once from the first main surface 14a side to the second main surface 14b side can be adopted in a configuration of the present invention other than the present example embodiment if so desired.

FIG. 14 is a schematic sectional view illustrating a vicinity of a first gap region of an acoustic wave device according to a fourth example embodiment of the present invention along the electrode finger extending direction.

The present example embodiment is different from the first example embodiment in that a notch side surface 54c is inclined from the first main surface 14a side to the second main surface 14b side of a piezoelectric layer 54 such that the distance between the facing surface portions is lengthened. Except for the above points, the acoustic wave device according to the present example embodiment preferably has the same or substantially the same configuration as the acoustic wave device 1 according to the first example embodiment.

As illustrated in FIG. 14, a first surface portion 58a facing a through hole 57 provided in a portion of the piezoelectric layer 54 located in the first gap region G1 overlaps the first busbar 26 in the plan view. A second surface portion 58b overlaps the second electrode finger 29 in the plan view. Although not illustrated, neither the third surface portion nor the fourth surface portion overlaps the first electrode finger in the plan view.

In other words, in the plan view, the first surface portion 58a opposing the through hole 57 overlaps the busbar among the busbar and the electrode finger that interpose the through hole 57 in the electrode finger extending direction in the plan view. The second surface portion 58b overlaps the electrode finger in the plan view among the busbars and the electrode fingers. In the plan view, neither the third surface portion nor the fourth surface portion opposing the through hole 57 overlaps the electrode fingers interposing the through hole 57 in the electrode finger opposing direction in the plan view. The same applies to each surface portion opposing the through hole 57 provided in the portion of the piezoelectric layer 54 located in the second gap region.

The disposition of each surface portion is not limited to the above-described disposition. For example, in the plan view, the first surface portion 58a opposing the through hole 57 need not overlap the busbar among the busbar and the electrode fingers that interpose the through hole 57 in the electrode finger extending direction in the plan view. The second surface portion 58b need not overlap the electrode finger in the plan view among the busbars and the electrode fingers. In the plan view, at least one of the third surface portion or the fourth surface portion opposing the through hole 57 may overlap the electrode fingers interposing the through hole 57 in the electrode finger opposing direction in the plan view.

Also in the present example embodiment, the unnecessary wave can be reduced or prevented at a frequency that is lower than the resonant frequency and is located near the resonant frequency, as in the first example embodiment.

The configuration in which the notch side surface 54c is inclined from the first main surface 14a side to the second main surface 14b side of the piezoelectric layer 54 such that the distance between the surface portions opposing each other is lengthened can be adopted in a configuration of the present invention other than the present example embodiment.

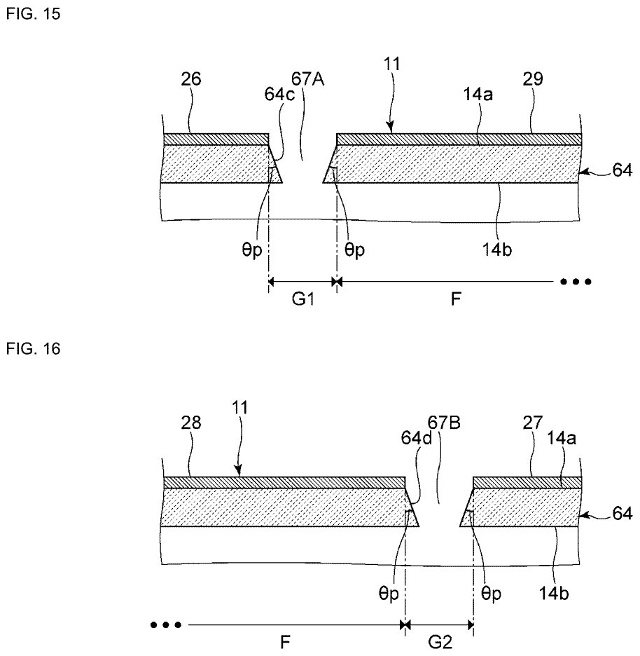

FIG. 15 is a schematic sectional view illustrating a vicinity of a first gap region of an acoustic wave device according to a fifth example embodiment of the present invention along the electrode finger extending direction. FIG. 16 is a schematic sectional view illustrating a vicinity of a second gap region of the acoustic wave device according to the fifth example embodiment along the electrode finger extending direction.

As illustrated in FIG. 15, in the present example embodiment, a notch side surface 64c preferably opposes a through hole 67A located in a portion of the piezoelectric layer 64 between the first busbar 26 and the second electrode finger 29. On the other hand, as illustrated in FIG. 16, a notch side surface 64d preferably opposes a through hole 67B located in a portion of the piezoelectric layer 64 between the second busbar 27 and the first electrode finger 28. As illustrated in FIGS. 15 and 16, the present example embodiment is different from the first example embodiment in that the inclination angle θp of the notch side surface 64c, and the inclination angle θp of the notch side surface 64d are different from each other. Except for the above points, the acoustic wave device according to the present example embodiment preferably has the same configuration as the acoustic wave device 1 according to the first example embodiment.

Also in the present example embodiment, the unnecessary wave can be reduced or prevented at a frequency that is lower than the resonant frequency and is located near the resonant frequency, as in the first example embodiment.

The notch side surface 64c and the notch side surface 64d are each uniformly inclined. Each of the notch side surfaces need not be uniformly inclined, as in the third example embodiment. Alternatively, as in the second example embodiment, the inclination angle θp of at least one surface portion among the plurality of surface portions may be different from the inclination angle θp of the other surface portion. In these cases as well, it is preferable that, in the piezoelectric layer 64, the inclination angle θp of at least a portion of the notch side surface 64c opposing the through hole 67A, and the inclination angle θp of at least a part of the notch side surface 64d opposing the through hole 67B are different from each other. As a result, it is possible to effectively disperse the unnecessary waves, and it is possible to effectively reduce or prevent the unnecessary waves.

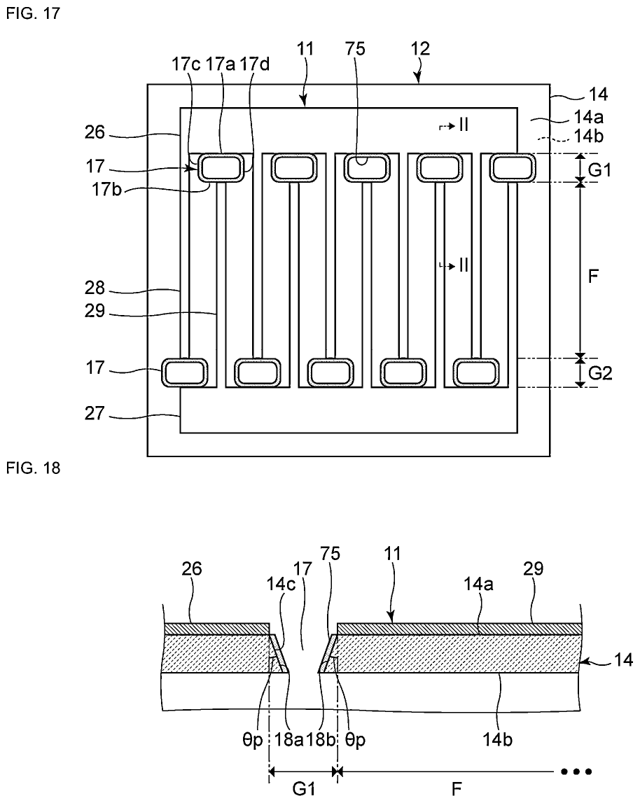

FIG. 17 is a schematic plan view of an acoustic wave device according to a sixth example embodiment of the present invention. FIG. 18 is a schematic sectional view taken along line II-II in FIG. 17 and illustrating the vicinity of the first gap region. In FIG. 17, the dielectric film described below is illustrated with hatching. The same applies to FIGS. 20 to 22 described below.

As illustrated in FIGS. 17 and 18, the present example embodiment is different from the first example embodiment in that the dielectric film 75 is provided on the notch side surface 14c of the piezoelectric layer 14. Except for the above points, the acoustic wave device according to the present example embodiment preferably has the same configuration as the acoustic wave device 1 according to the first example embodiment.

More specifically, the dielectric film 75 is not provided on the first main surface 14a of the piezoelectric layer 14, and the dielectric film 75 is provided on the notch side surface 14c. As a material of the dielectric film 75, for example, silicon oxide, tantalum oxide, or silicon nitride can be used.

Also in the present example embodiment, the unnecessary wave can be suppressed at a frequency that is lower than the resonant frequency and is located near the resonant frequency, as in the first example embodiment. In addition, the loss can be improved in the acoustic wave device. The details of the effects of the present example embodiment are illustrated by comparing the present example embodiment with a second comparative example.

The second comparative example is different from the sixth example embodiment in that the inclination angle θp on the notch side surface is 0°. Impedance frequency characteristics of the acoustic wave device according to the sixth example embodiment and the second comparative example are compared by performing simulation.

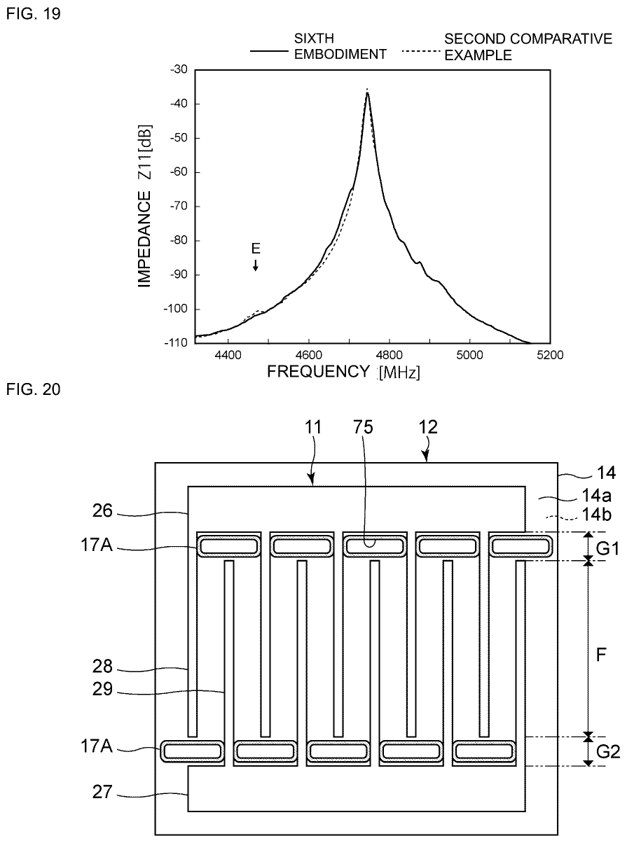

FIG. 19 is a diagram illustrating the impedance frequency characteristics according to the sixth example embodiment and the second comparative example.

As indicated by an arrow E in FIG. 19, in the second comparative example, the ripples caused by the unnecessary waves are generated at a frequency that is lower than the resonant frequency and is located near the resonant frequency. On the other hand, it can be seen that the unnecessary wave generated at the frequency is suppressed in the sixth example embodiment.

Hereinafter, first to third modified examples of the sixth example embodiment are described in which only the disposition or the shape of the through hole is different from those in the sixth example embodiment. Also in the first to third modified examples, the unnecessary wave can be suppressed and the loss can be improved, as in the sixth example embodiment.

In the first modified example illustrated in FIG. 20, the shape of the through hole 17A in the plan view is the same or substantially the same as the shape of the through hole 17 in the sixth example embodiment. The through hole 17A is not in contact with the busbar and the distal end of the electrode finger that interpose the through hole 17A in the electrode finger extending direction in the plan view and is in contact with the electrode fingers interposing the through hole in the electrode finger opposing direction.

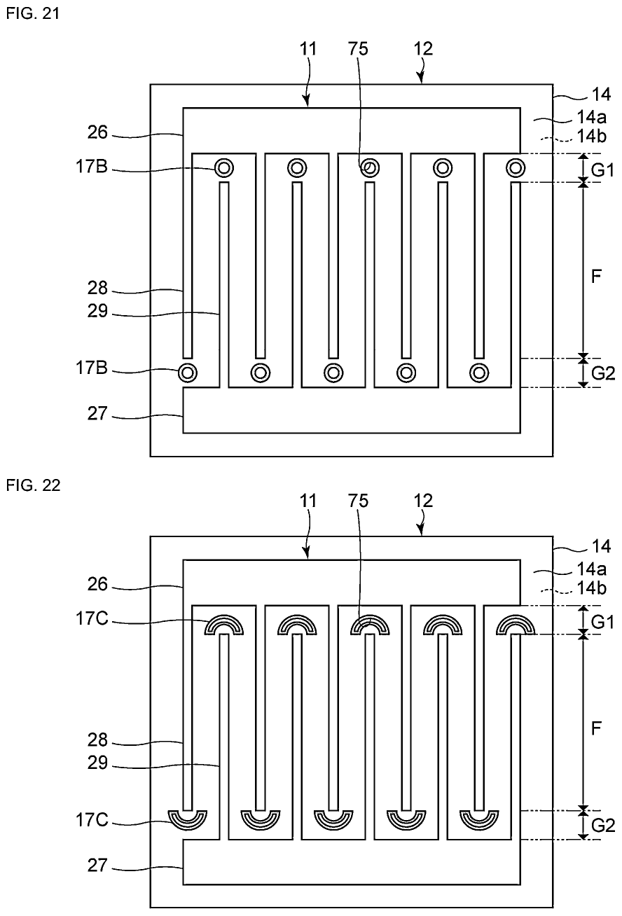

In the second modified example illustrated in FIG. 21, the shape of the through hole 17B in the plan view is a circular or substantially circular shape. The through hole 17B is not in contact with any of the busbar or the distal end of the electrode finger that interposes the through hole 17B in the electrode finger extending direction in the plan view, or the electrode fingers interposing the through hole 17B in the electrode finger opposing direction.

In the third modified example illustrated in FIG. 22, the shape of the through hole 17C in the plan view is substantially a crescent shape. More specifically, the shape of the through hole 17C in the plan view is a shape including two semicircular shapes in which two concentric circles are divided by the same straight line passing through the centers of the two concentric circles, and the two semicircular shapes are connected to each other.

In the plan view, the through hole 17C is not in contact with any of the busbar or the distal end of the electrode finger that interposes the through hole 17C in the electrode finger extending direction, or the electrode fingers interposing the through hole 17C in the electrode finger opposing direction.

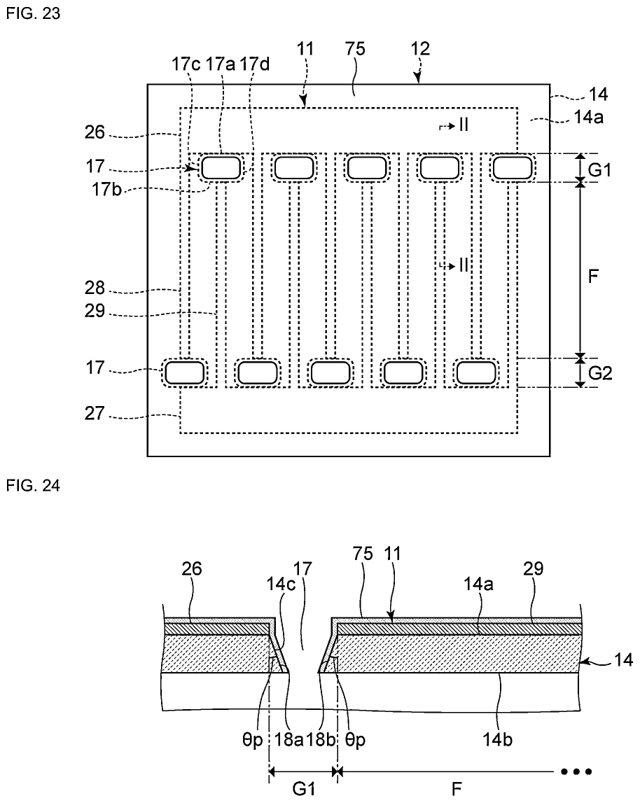

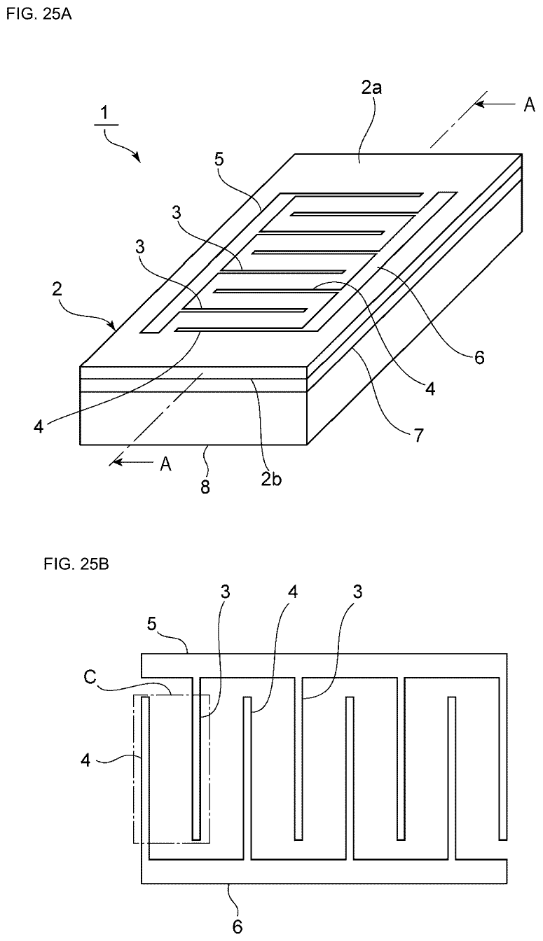

FIG. 23 is a schematic plan view of an acoustic wave device according to a seventh example embodiment of the present invention. FIG. 24 is a schematic sectional view taken along line II-II in FIG. 23 and illustrating the vicinity of the first gap region.

The present example embodiment is different from the sixth example embodiment in that the dielectric film 75 is provided on the first main surface 14a of the piezoelectric layer 14. Except for the above points, the acoustic wave device according to the present example embodiment preferably has the same or substantially the same configuration as the acoustic wave device according to the sixth example embodiment. Therefore, the notch side surface 14c of the piezoelectric layer 14 is also provided with the dielectric film 75.

Also in the present example embodiment, the unnecessary wave can be reduced or prevented at the frequency located near the resonant frequency, as in the sixth example embodiment. Additionally, the loss can be improved.

Further, the dielectric film 75 is provided to cover the IDT electrode 11.

As a result, the dielectric film 75 defines and functions as a protective film of the IDT electrode 11. As a result, the IDT electrode 11 is less likely to be damaged. In a case where the dielectric film 75 is provided, the moisture resistance can also be improved. The frequency can also be easily adjusted by adjusting the thickness of the portion of the dielectric film 75 that overlaps the excitation region in the plan view.

Hereinafter, the details of the thickness shear mode will be described. The “electrode” in the IDT electrode described later corresponds to an electrode finger according to the present invention. The support in the following example corresponds to a support substrate.

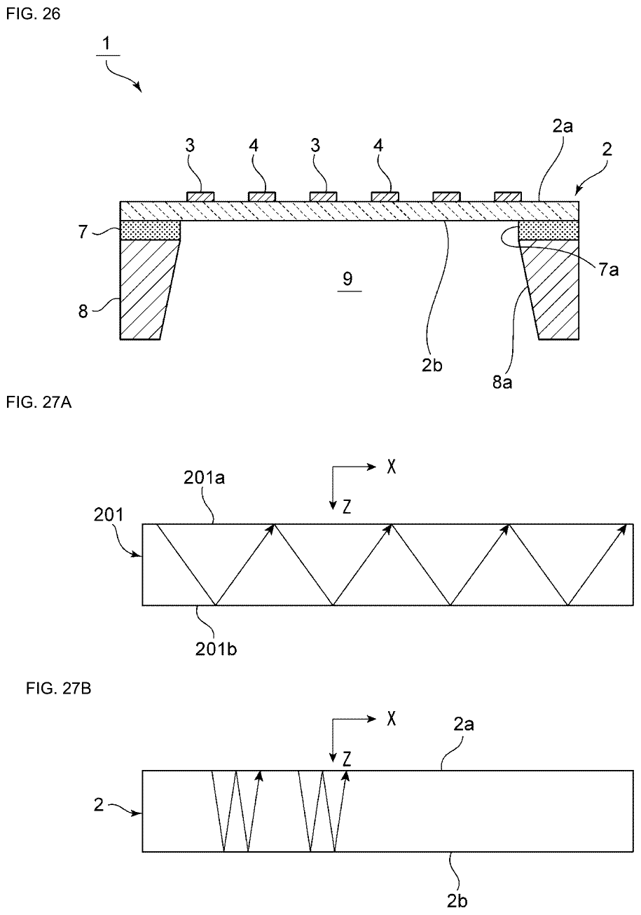

FIG. 25A is a schematic perspective view illustrating an appearance of the acoustic wave device using the bulk wave in the thickness shear mode, and FIG. 25B is a plan view illustrating the electrode structure on the piezoelectric layer, and FIG. 26 is a sectional view of a portion taken along line A-A in FIG. 25A.

An acoustic wave device 1 preferably includes a piezoelectric layer 2 made of, for example, LiNbO₃. The piezoelectric layer 2 may alternatively be made of, for example, LiTaO₃. A cut-angle of LiNbO₃ or LiTaO₃ is a Z cut, but may be a rotation Y cut or an X cut. The thickness of the piezoelectric layer 2 is not particularly limited, but, for example, is preferably about 40 nm or more and about 1000 nm or less, and more preferably about 50 nm or more and about 1000 nm or less in order to effectively excite the thickness shear mode. The piezoelectric layer 2 preferably includes first and second main surfaces 2a and 2b opposing each other. Electrodes 3 and 4 are preferably provided on the first main surface 2a. Here, the electrode 3 is an example of a “first electrode” and the electrode 4 is an example of a “second electrode”. In FIGS. 25A and 25B, the plurality of electrodes 3 are a plurality of first electrode fingers connected to a first busbar 5. The plurality of electrodes 4 are a plurality of second electrode fingers connected to a second busbar 6. The plurality of electrodes 3 and the plurality of electrodes 4 are interdigitated with each other. Each of the electrodes 3 and 4 has a rectangular or substantially rectangular shape and a length direction. The electrode 3 and the electrode 4 adjacent thereto oppose each other in a direction orthogonal or substantially orthogonal to the length direction. Both the length direction of the electrodes 3 and 4 and the direction orthogonal or substantially orthogonal to the length direction of the electrodes 3 and 4 are directions intersecting a thickness direction of the piezoelectric layer 2. Therefore, it can be said that the electrode 3 and the electrode 4 adjacent thereto oppose each other in the direction intersecting the thickness direction of the piezoelectric layer 2. In addition, the length direction of the electrodes 3 and 4 may be changed to the direction orthogonal or substantially orthogonal to the length direction of the electrodes 3 and 4 illustrated in FIGS. 25A and 25b. That is, in FIGS. 25A and 25B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 25A and 25B. A plurality of pairs of structures in which the electrode 3 connected to one potential and the electrode 4 connected to the other potential are adjacent to each other are provided in a direction orthogonal or substantially orthogonal to the length direction of the electrodes 3 and 4. Here, a case where the electrodes 3 and 4 are adjacent to each other does not mean a case where the electrodes 3 and 4 are disposed to be in direct contact with each other, but mean a case where the electrodes 3 and 4 are disposed with a gap therebetween. In a case where the electrodes 3 and 4 are adjacent to each other, the electrodes connected to a hot electrode or a ground electrode, including the other electrodes 3 and 4, are not disposed between the electrodes 3 and 4. The number of pairs does not have to be integer pairs and may be 1.5 pairs, 2.5 pairs, or the like. The center-to-center distance, that is, the pitch between the electrodes 3 and 4 is, for example, preferably in a range of about 1 μm or more and about 10 μm or less. The widths of the electrodes 3 and 4, that is, the dimensions of the electrodes 3 and 4 in the opposing direction are, for example, preferably in a range of about 50 nm or more and about 1000 nm or less, and more preferably in a range of about 150 nm or more and about 1000 nm or less. The center-to-center distance between the electrodes 3 and 4 is a distance connecting the center of the dimension (width dimension) of the electrode 3 in the direction orthogonal or substantially orthogonal to the length direction of the electrode 3 and the center of the dimension (width dimension) of the electrode 4 in the direction orthogonal or substantially orthogonal to the length direction of the electrode 4.

In the acoustic wave device 1, since the Z-cut piezoelectric layer is used, the direction orthogonal or substantially orthogonal to the length direction of the electrodes 3 and 4 is a direction orthogonal or substantially orthogonal to a polarization direction of the piezoelectric layer 2. This shall not be applied to case where a piezoelectric material with a different cut-angle is used as the piezoelectric layer 2. Here, “orthogonal” is not limited to being strictly orthogonal, but may be substantially orthogonal (angle between the direction orthogonal to the length direction of the electrodes 3 and 4 and the polarization direction is preferably, for example, in a range of about 90°±10°.

A support 8 is laminated on the second main surface 2b side of the piezoelectric layer 2 with an insulating layer 7 interposed therebetween. The insulating layer 7 and the support 8 have a frame shape and include through holes 7a and 8a as illustrated in FIG. 26. As a result, a cavity portion 9 is provided. The cavity portion 9 is provided not to disturb the vibration of the excitation region C of the piezoelectric layer 2. Therefore, the support 8 is laminated on the second main surface 2b with the insulating layer 7 interposed therebetween at a position not overlapping the portion in which at least the pair of electrodes 3 and 4 are provided. The insulating layer 7 does not have to be provided. Therefore, the support 8 can be directly or indirectly laminated on the second main surface 2b of the piezoelectric layer 2.

The insulating layer 7 is, for example, preferably made of silicon oxide. In addition to silicon oxide, an appropriate insulating material such as, for example, silicon oxynitride or alumina can be alternatively used. The support 8 is, for example, preferably made of Si. A plane orientation of the plane of Si on the piezoelectric layer 2 side may be (100), (110), or (111). Si of the support 8 is preferably high resistance having a resistivity of, for example, about 4 kΩcm or more. The support 8 can also be made of an appropriate insulating material or semiconductor material.

Examples of the material of the support 8 include piezoelectric materials such as, for example, aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3 and 4 and the first and second busbars 5 and 6 are made of appropriate metals or alloys such as, for example, Al and AlCu alloys. In the present example embodiment, the electrodes 3 and 4 and the first and second busbars 5 and 6 have a structure in which an Al film is laminated on a Ti film. An adhesion layer other than the Ti film may be used.

During driving, the AC voltage is applied between the plurality of electrodes 3 and the plurality of electrodes 4. More specifically, the AC voltage is applied between the first busbar 5 and the second busbar 6. As a result, it is possible to obtain the resonance characteristics using the bulk wave in the thickness shear mode excited in the piezoelectric layer 2. In the acoustic wave device 1, for example, d/p is about 0.5 or less, where d is the thickness of the piezoelectric layer 2 and p is the center-to-center distance between any adjacent electrodes 3 and 4 among the plurality of pairs of electrodes 3 and 4. As a result, the bulk wave in the thickness shear mode is effectively excited, and good resonance characteristics can be obtained. More preferably, for example, d/p is about 0.24 or less, and in this case, better resonance characteristics can be obtained.

In the acoustic wave device 1, since the above-described configuration is provided, even in a case where the number of pairs of the electrodes 3 and 4 is reduced in order to reduce the size, a Q value is less likely to be decreased. This is because the propagation loss is small even in a case where the number of electrode fingers in the reflectors on respective sides is small. In addition, the number of electrode fingers can be reduced by using the bulk wave in the thickness shear mode. A difference between the Lamb wave used in the acoustic wave device and the bulk wave in the thickness shear mode will be described with reference to FIGS. 27A and 27B.

FIG. 27A is a schematic elevational sectional view illustrating the Lamb wave that propagates through the piezoelectric film of the acoustic wave device as disclosed in Japanese Unexamined Patent Application Publication No. 2012-257019. Here, the wave propagates in a piezoelectric film 201 as indicated by an arrow. Here, in the piezoelectric film 201, a first main surface 201a and a second main surface 201b oppose each other, and a thickness direction connecting the first main surface 201a and the second main surface 201b is a Z direction. An X direction is a direction in which the electrode fingers of the IDT electrodes are arranged. As illustrated in FIG. 27A, in the Lamb wave, the wave propagates in the X direction as illustrated in the figure. Since the wave is a plate wave, although the piezoelectric film 201 vibrates as a whole, since the wave propagates in the X direction, the reflectors are disposed on respective sides to obtain the resonance characteristics. Therefore, the propagation loss of the wave occurs, and the Q value is decreased in a case where the size reduction is attempted, that is, in a case where the number of pairs of the electrode fingers is decreased.

On the other hand, as illustrated in FIG. 27B, in the acoustic wave device 1, since the vibration displacement is a thickness shear direction, the wave propagates and resonates in the direction connecting the first main surface 2a and the second main surface 2b of the piezoelectric layer 2, that is, the Z direction. That is, an X-direction component of the wave is significantly smaller than a Z-direction component. In addition, since the resonance characteristics are obtained by the propagation of the wave in the Z direction, the propagation loss is less likely to occur even when the number of the electrode fingers of the reflector is reduced. Further, even in a case where the number of pairs of the electrode pair includes the electrodes 3 and 4 is reduced when the size reduction is attempted, the Q value is less likely to be decreased.

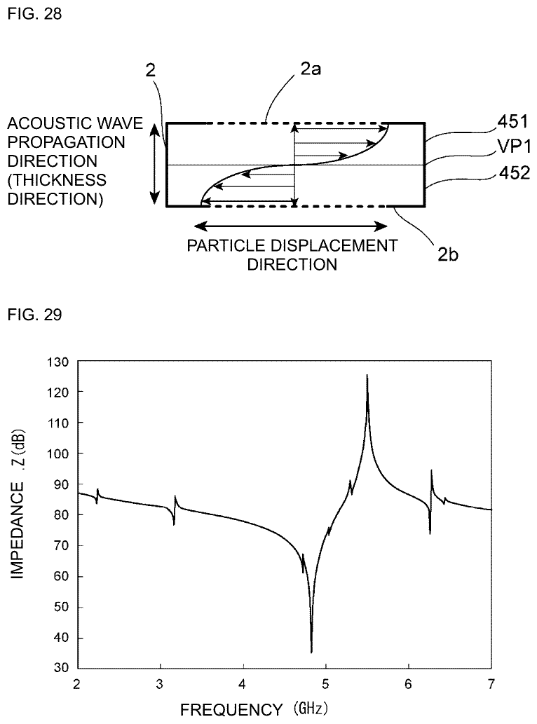

Amplitude directions of the bulk waves of the thickness shear mode are opposite to each other between a first region 451 included in the excitation region C of the piezoelectric layer 2 and a second region 452 included in the excitation region C, as illustrated in FIG. 28. FIG. 28 schematically illustrates the bulk waves when the voltage is applied between the electrodes 3 and 4 so that the potential of the electrode 4 is higher than the potential of the electrode 3. The first region 451 is a region of the excitation region C between a virtual plane VP1, which is orthogonal to the thickness direction of the piezoelectric layer 2 and bisects the piezoelectric layer 2, and the first main surface 2a. The second region 452 is a region of the excitation region C between the virtual plane VP1 and the second main surface 2b.

As described above, in the acoustic wave device 1, although at least the pair of electrodes including the electrodes 3 and 4 are disposed, the waves are not propagated in the X direction, and thus the number of pairs of the electrode pair consisting of the electrodes 3 and 4 does not have to be plural. That is, at least the pair of electrodes need only be provided. For example, the electrode 3 is an electrode connected to a hot potential and the electrode 4 is an electrode connected to a ground potential. The electrode 3 may be connected to the ground potential and the electrode 4 may be connected to the hot potential. In the present example embodiment, at least a pair of electrodes are the electrodes connected to the hot potential or the electrodes connected to the ground potential, as described above, and no floating electrodes are provided.

FIG. 29 is a diagram illustrating the resonance characteristics of the acoustic wave device illustrated in FIG. 26. The design parameters of the acoustic wave device 1 with the resonance characteristics are as follows.

Piezoelectric layer 2: LiNbO₃ with Euler angles (0°, 0°, 90°, thickness=about 400 nm.

When viewed in the direction orthogonal to the length direction of the electrodes 3 and 4, the length of the region in which the electrodes 3 and 4 overlap each other, that is, the length of the excitation region C=about 40 μm, the number of pairs of the electrodes consisting of the electrodes 3 and 4=21 pairs, the center-to-center distance between the electrodes=about 3 μm, the width of the electrodes 3 and 4=about 500 nm, and d/p=about 0.133.

Insulating layer 7: silicon oxide film having thickness of about 1 μm.

Support 8: Si.

The length of the excitation region C is the dimension along the length direction of the electrodes 3 and 4 of the excitation region C.

In the present example embodiment, the electrode-to-electrode distances of the electrode pairs including the electrodes 3 and 4 are all equal or substantially equal in the plurality of pairs. That is, the electrodes 3 and 4 are disposed at equal or substantially equal pitches.

As is clear from FIG. 29, good resonance characteristics with the fractional bandwidth of about 12.5% are obtained regardless of the presence of the reflector.

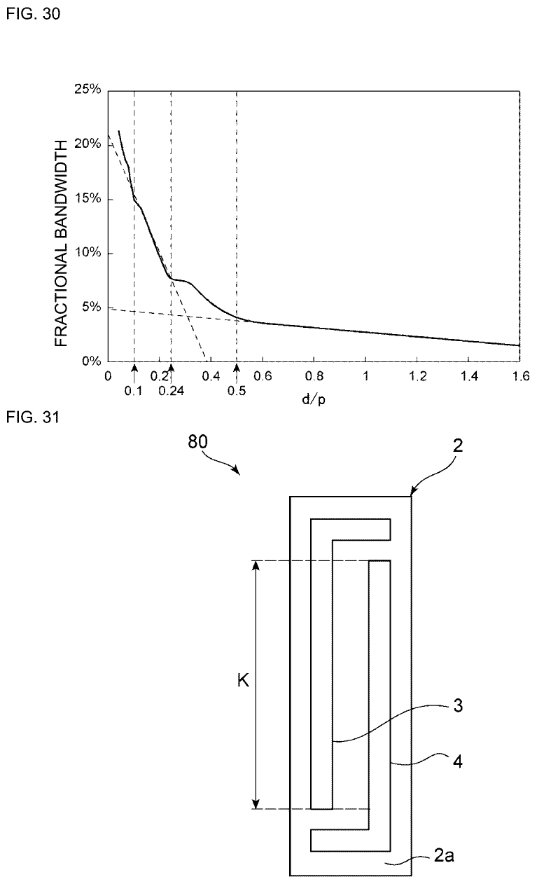

In the present example embodiment, as described above, d/p is, for example, about 0.5 or less, and more preferably about 0.24 or less, where d is the thickness of the piezoelectric layer 2 and p is the center-to-center distance between the electrodes 3 and 4. The description thereof will be made with reference to FIG. 30.

A plurality of acoustic wave devices are obtained by changing d/p in the same or substantially the same manner as the acoustic wave device that obtains the resonance characteristics illustrated in FIG. 29. FIG. 30 is a diagram illustrating a relationship between d/p and the fractional bandwidth as the resonator of the acoustic wave device.

As is clear from FIG. 30, when d/p>about 0.5, the fractional bandwidth is less than about 5% even in a case where d/p is adjusted. On the other hand, in a case where d/p≤about 0.5, when d/p is changed within this range, the fractional bandwidth of about 5% or more can be obtained, that is, the resonator having a high coupling coefficient can be provided. In addition, in a case where d/p is about 0.24 or less, the fractional bandwidth can be increased to about 7% or more. In addition, by adjusting d/p within this range, a resonator with a wider fractional bandwidth can be obtained, and a resonator with a higher coupling coefficient can be realized. Therefore, it was discovered that, by adjusting d/p to, for example, about 0.5 or less, it is possible to configure a resonator having a high coupling coefficient using the bulk wave in the thickness shear mode.

FIG. 31 is a plan view of the acoustic wave device using the bulk wave in the thickness shear mode. In an acoustic wave device 80, the pair of electrodes including the electrode 3 and electrode 4 are provided on the first main surface 2a of the piezoelectric layer 2. K in FIG. 31 is an intersecting width. As described above, in the acoustic wave device according to the present invention, the number of pairs of the electrodes may be one pair. Even in this case, when d/p is about 0.5 or less, it is possible to effectively excite the bulk wave in the thickness shear mode.

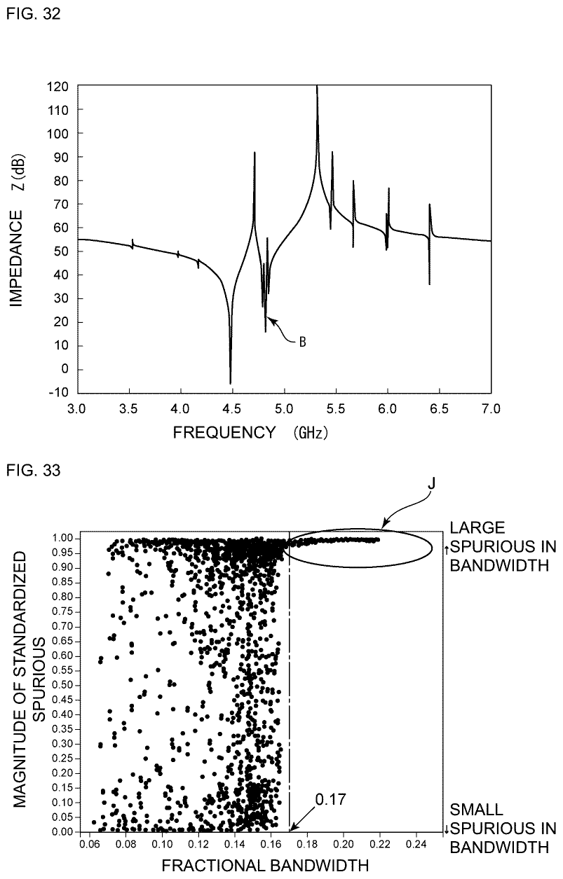

In the acoustic wave device 1, preferably, it is desirable that MR≤about 1.75 (d/p)+0.075 is satisfied, where MR is a metallization ratio of any adjacent electrodes 3 and 4 among the plurality of electrodes 3 and 4 to the excitation region C, which is the region in which the adjacent electrodes 3 and 4 overlap each other when viewed in the opposing direction. In this case, the spurious wave can be effectively reduced. The description thereof will be made with reference to FIGS. 32 and 33. FIG. 32 is a reference view illustrating an example of the resonance characteristics of the acoustic wave device 1. The spurious wave indicated by an arrow B appears between the resonant frequency and the anti-resonant frequency. d/p=about 0.08 and the Euler angles of LiNbO₃ are (0°, 0°, 90°. Also, the metallization ratio MR is about 0.35.

The metallization ratio MR will be described with reference to FIG. 25B. In the electrode structure of FIG. 25B, it is assumed that, when focusing on the pair of electrodes 3 and 4, only the pair of electrodes 3 and 4 are provided. In this case, a portion surrounded by a one-dot chain line is the excitation region C. The excitation region C is a region of the electrode 3 that overlaps the electrode 4 when the electrode 3 and the electrode 4 are viewed in the direction orthogonal or substantially orthogonal to the length direction of the electrodes 3 and 4, that is, in the facing direction, a region of the electrode 4 that overlaps the electrode 3, and a region in which the electrode 3 and the electrode 4 overlap each other in the region between the electrode 3 and the electrode 4. An area of the electrodes 3 and 4 in the excitation region C with respect to an area of this excitation region C is the metallization ratio MR. That is, the metallization ratio MR is a ratio of an area of the metallization portion to the area of the excitation region C.

In a case where the plurality of pairs of electrodes are provided, a ratio of the metallization portion included in the entire excitation region to a total area of the excitation region need only be MR.

FIG. 33 is a diagram illustrating a relationship between a fractional bandwidth and a phase rotation amount of an impedance of the spurious wave standardized at about 180 degrees as a magnitude of the spurious wave in a case where a large number of acoustic wave resonators are configured according to the present example embodiment. The fractional bandwidth is adjusted by changing the film thickness of the piezoelectric layer and the dimensions of the electrodes. Moreover, FIG. 33 illustrates the results in a case where the piezoelectric layer formed of the Z-cut LiNbO₃ is used, but the same tendency is obtained in a case where piezoelectric layers with other cut-angles are used.

In a region surrounded by an ellipse J in FIG. 33, the spurious wave is as large as about 1.0. As is clear from FIG. 33, in a case where the fractional bandwidth exceeds about 0.17, that is, exceeds about 17%, a large spurious wave with a spurious wave level of about 1 or more appears in a pass band even when the parameters constituting the fractional bandwidth are changed. That is, as in the resonance characteristics illustrated in FIG. 32, a large spurious wave indicated by an arrow B appears in the band. Therefore, the fractional bandwidth is, for example, preferably about 17% or less.

In this case, by adjusting the film thickness of the piezoelectric layer 2 and the dimensions of the electrodes 3 and 4, the spurious wave can be reduced.

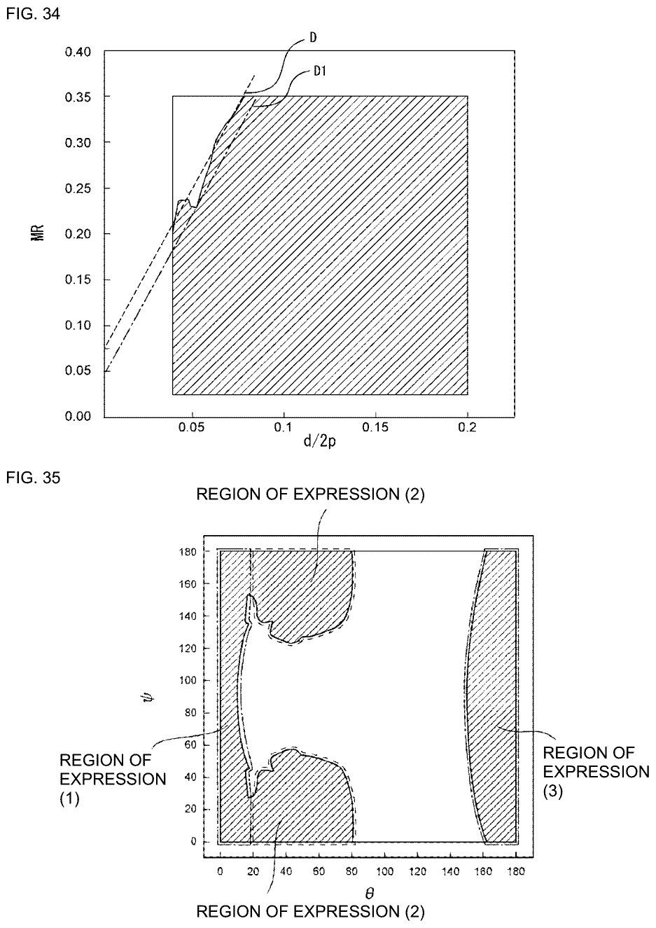

FIG. 34 is a diagram illustrating a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 34 is a region in which the fractional bandwidth is about 17% or less. A boundary between the hatched region and a non-hatched region is expressed by MR=about 3.5(d/2p)+0.075. That is, MR=about 1.75 (d/p)+0.075. Therefore, preferably, MR≤about 1.75 (d/p)+0.075. In this case, it is easy to set the fractional bandwidth to about 17% or less. More preferably, it is a region on a right side of MR=about 3.5 (d/2p)+0.05 indicated by a one-dot chain line D1 in FIG. 34. That is, in a case where MR≤about 1.75 (d/p)+0.05, the fractional bandwidth can be reliably set to about 17% or less.

FIG. 35 is a diagram illustrating a map of the fractional bandwidth with respect to Euler angles (0°, θ, ψ) of LiNbO₃ in a case where d/p is infinitely close to 0. A hatched portion in FIG. 35 is a region in which the fractional bandwidth of at least 5% or more is obtained, and in a case where a range of the region is approximated, the range is a range represented by Expressions (1), (2), and (3).

$$( 0 ° \pm 10 ° , 0 ° to 20 ° , any ψ ) \qquad Expression ( 1 )$$

$$( 0 ° \pm 10 ° , 20 ° to 80 ° , 0 ° to 60 ° {( 1 - {( θ - 50 )}^{2} / 900 )}^{1 / 2} ) \qquad Expression ( 2 )$$

$$or$$

$$( 0 ° \pm 10 ° , 20 ° to 80 ° , [ 180 ° - 60 {° ( 1 - {( θ - 50 )}^{2} / 900 )}^{1 / 2} ] to 180 ° )$$

$$Expression ( 3 )$$

$$( 0 ° \pm 10 ° , [ 180 ° - 30 {° ( 1 - {( ψ - 90 )}^{2} / 8100 )}^{1 / 2} ] 180 ° , any ψ )$$

Therefore, in a case of the Euler angle range of Expression (1), Expression (2), or Expression (3), the fractional bandwidth can be sufficiently widened, which is preferable. The same applies to a case where the piezoelectric layer 2 is the lithium tantalate layer.

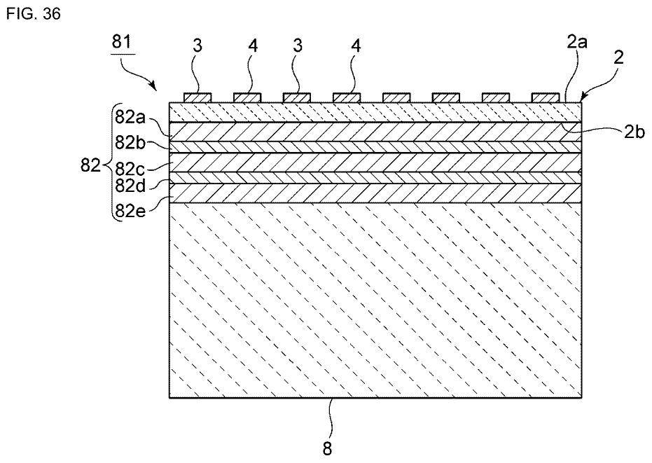

FIG. 36 is an elevational sectional view of an acoustic wave device including an acoustic multilayer film.

In an acoustic wave device 81, an acoustic multilayer film 82 is laminated on the second main surface 2b of the piezoelectric layer 2. The acoustic multilayer film 82 has a laminated structure of low acoustic impedance layers 82a, 82c, and 82e having a relatively low acoustic impedance and high acoustic impedance layers 82b and 82d having a relatively high acoustic impedance. In a case where the acoustic multilayer film 82 is used, the bulk wave in the thickness shear mode can be confined in the piezoelectric layer 2 without using the cavity portion 9 of the acoustic wave device 1. Also in the acoustic wave device 81, the resonance characteristics based on the bulk wave in the thickness shear mode can be obtained by adjusting d/p to about 0.5 or less. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d need only be disposed on a side farther from the piezoelectric layer 2 than the low acoustic impedance layers 82a, 82c, and 82e.

The low acoustic impedance layers 82a, 82c, and 82e and the high acoustic impedance layers 82b and 82d can be made of an appropriate material as long as the above-described relationship of the acoustic impedance is satisfied. Examples of the materials of the low acoustic impedance layers 82a, 82c, and 82e include silicon oxide and silicon oxynitride. In addition, examples of the materials of the high acoustic impedance layers 82b and 82d include alumina, silicon nitride, and metal.

In the acoustic wave devices according to the first to seventh example embodiments and each of the modified examples, for example, the acoustic multilayer film 82 illustrated in FIG. 36 may be provided as the acoustic reflection film between the support and the piezoelectric layer. Specifically, the support and the piezoelectric layer may be disposed such that at least a part of the support and at least a portion of the piezoelectric layer oppose each other with the acoustic multilayer film 82 interposed therebetween. In this case, in the acoustic multilayer film 82, the low acoustic impedance layer and the high acoustic impedance layer need only be alternately laminated. The acoustic multilayer film 82 may be the acoustic reflection portion in the acoustic wave device.

In the acoustic wave devices according to the first to seventh example embodiments and each of the modified examples that use the bulk wave in the thickness shear mode, as described above, d/p is, for example, preferably about 0.5 or less, and more preferably about 0.24 or less. As a result, better resonance characteristics can be obtained. Further, in the excitation regions in the acoustic wave devices according to the first to seventh example embodiments and each of the modified examples that use the bulk wave in the thickness shear mode, as described above, preferably, MR≤about 1.75 (d/p)+0.075 is satisfied. In this case, it is possible to more reliably reduce or prevent the formation of a spurious wave.

It is preferable that the piezoelectric layers in the acoustic wave devices according to the first to seventh example embodiments and each of the modified examples that use the bulk wave in the thickness shear mode is the lithium niobate layer or the lithium tantalate layer, for example. In addition, it is preferable that the Euler angles (φ, θ, ψ) of lithium niobate or lithium tantalate forming the piezoelectric layer are in the range of Expression (1), Expression (2), or Expression (3). In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer on the support, made of lithium niobate or lithium tantalate, and including a first main surface and a second main surface that oppose each other; and
an interdigital transducer (IDT) electrode on the first main surface of the piezoelectric layer; wherein
an acoustic reflection portion is provided at a position overlapping at least a portion of the IDT electrode in a plan view when viewed along a laminating direction of the support and the piezoelectric layer;
the IDT electrode includes a first busbar and a second busbar that oppose each other, first electrode fingers each including one end connected to the first busbar, and second electrode fingers each including one end connected to the second busbar and being interdigitated with the first electrode fingers;
d/p is about 0.5 or less, where d is a thickness of the piezoelectric layer and p is a center-to-center distance between one of the first electrode fingers and one of the second electrode fingers that are adjacent to each other;
the piezoelectric layer includes at least one through hole, and one of the at least one through hole is provided in a portion of the piezoelectric layer between the first busbar and any one of the second electrode fingers; and
the piezoelectric layer includes a notch side surface connected to the first main surface and the second main surface and opposing the through hole; and
where an inclination angle of the notch side surface is an angle of the notch side surface inclined with respect to a line normal to the first main surface and the second main surface, the inclination angle is other than 0°.

2. The acoustic wave device according to claim 1, wherein the inclination angle of the notch side surface is changed at least once from a first main surface side to a second main surface side.

3. The acoustic wave device according to claim 1, wherein a shape of the through hole in the plan view is a shape including a plurality of sides, and the notch side surface includes surface portions respectively including the sides.

4. The acoustic wave device according to claim 3, wherein the shape of the through hole in the plan view is a shape in which a portion corresponding to a vertex of a polygon is curved.

5. The acoustic wave device according to claim 3, wherein an inclination angle of at least a portion of at least one surface portion is different from an inclination angle of at least a portion of another surface portion, among the plurality of surface portions.

6. The acoustic wave device according to claim 1, wherein the piezoelectric layer includes through holes included in the at least one through hole, and one of the through holes is provided in a portion of the piezoelectric layer between the second busbar and any one of the first electrode fingers.

7. The acoustic wave device according to claim 6, wherein some of the through holes are provided in respective portions of the piezoelectric layer between the first busbar and the second electrode fingers, and others of the through holes are provided in respective portions of the piezoelectric layer between the second busbar and the first electrode fingers.

8. The acoustic wave device according to claim 6, wherein an inclination angle of at least a portion of a notch side surface opposing a through hole located in a portion of the piezoelectric layer between the first busbar and a second electrode finger and an inclination angle of at least a portion of a notch side surface opposing a through hole located in a portion of the piezoelectric layer between the second busbar and a first electrode finger are different from each other.

9. The acoustic wave device according to claim 1, further comprising a dielectric film on the notch side surface of the piezoelectric layer.

10. The acoustic wave device according to claim 1, wherein the acoustic reflection portion is a cavity portion, and the support and the piezoelectric layer are positioned such that a portion of the support and a portion of the piezoelectric layer oppose each other with the cavity portion interposed therebetween.

11. The acoustic wave device according to claim 1, wherein the acoustic reflection portion is an acoustic reflection film including a high acoustic impedance layer having a relatively high acoustic impedance and a low acoustic impedance layer having a relatively low acoustic impedance, and the support and the piezoelectric layer are positioned such that at least a portion of the support and at least a portion of the piezoelectric layer oppose each other with the acoustic reflection film interposed therebetween.

12. The acoustic wave device according to claim 1, wherein d/p is about 0.24 or less.

13. The acoustic wave device according to claim 1, wherein MR≤about 1.75 (d/p)+0.075 is satisfied, where a region in which the one of the first electrode fingers and the one of the second electrode fingers that are adjacent to each other overlap each other when viewed from a direction in which the one of the first electrode fingers and the one of the second electrode fingers oppose each other and which is between centers of the one of the first electrode fingers and the one of the second electrode fingers that are adjacent to each other is an excitation region, and where a metallization ratio of the first electrode fingers and the second electrode fingers to the excitation region is MR.

14. The acoustic wave device according to claim 1, wherein
Euler angles (φ, θ, ψ) of the lithium niobate or the lithium tantalate defining the piezoelectric layer is in a range of at least one of the following expressions:
$$( 0 ° \pm 10 ° , 0 ° to 20 ° , any ψ ) ;$$
$$( 0 ° \pm 10 ° , 20 ° to 80 ° , 0 ° to 60 ° {( 1 - {( θ - 50 )}^{2} / 900 )}^{1 / 2} ) or$$
$$( 0 ° \pm 10 ° , 20 ° to 80 ° , [ 180 ° - 60 {° ( 1 - {( θ - 50 )}^{2} / 900 )}^{1 / 2} ] to 180 ° ) ; and$$
$$( 0 ° \pm 10 ° , [ 180 ° - 30 {° ( 1 - {( ψ - 90 )}^{2} / 8100 )}^{1 / 2} ] 180 ° , any ψ ) .$$

15. The acoustic wave device according to claim 1, further comprising:
an insulating layer between the piezoelectric layer and the support substrate; wherein
the insulating layer is made of a lithium niobate layer or a lithium tantalate layer.

16. The acoustic wave device according to claim 15, wherein the insulating layer includes a recess portion defining a cavity portion which defines and functions as the acoustic reflection portion.

17. The acoustic wave device according to claim 1, wherein the through hole includes four sides.

18. The acoustic wave device according to claim 1, wherein the through hole has a crescent or arch shape.

19. The acoustic wave device according to claim 1, wherein the inclination angle of the notch side surface of the piezoelectric layer changes.

20. The acoustic wave device according to claim 1, wherein the dielectric film further covers portions of the IDT electrode.
